(19) United States
(12) Patent Application Publication
(10) Pub. No.: US 2009/0127702 A1
(43) Pub. Date: May 21, 2009

(54) PACKAGE, SUBASSEMBLY AND METHODS OF MANUFACTURING THEREOF

(75) Inventors: Ronald Dekker, Eindhoven (NL); Theodorus Martinus Michielsen, Eindhoven (NL); Eduard Johannes Meijer, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., Eindhoven (NL)

(21) Appl. No.: 12/282,653

(22) PCT Filed: Jun. 22, 2006
(86) PCT No.: PCT/IB2006/052034

§ 371 Date: Sep. 12, 2008

(30) Foreign Application Priority Data
Jun. 29, 2005 (EP) 05105830.3

(51) Int. Cl. H01L 23/36; H01L 21/768

(52) U.S. Cl. 257/713; 438/122; 438/124; 257/E23.101; 257/E21.575

(57) ABSTRACT

The package (100) of the invention comprises at least one semiconductor device (30) provided with bond pads (32); an encapsulation (40), an interconnect element (20) and a heatsink (90). This element comprises a system of electrical interconnects (12) and is at least substantially covered by a thermally conductive, electrically insulating layer (11) at a first side (1) and that is provided with an electric isolation (13) at a second side (2), such that the isolation (13) and the thermally conducting layer (11) electrically isolate the electrical interconnects (12) from each other. At least one component of the encapsulation (40) and the heatsink (90) has an interface with the interconnect element (20), which interlace extends over substantially the complete side (1,2) to which the said component (40,90) is attached.

The invention relates to a package for at least one semiconductor device comprising:

at least one semiconductor device provided with bond pads, and,

an interconnect element with a first side and an opposite second side, which element comprises a system of electrical interconnects that is at least substantially covered by a thermally conducting layer at the first side and that is provided with an electric isolation at the second side, which electric isolation is provided with apertures that expose contact pads defined in the interconnects, to which contact pads the bond pads of the at least one semiconductor device are electrically coupled, which interconnect element is provided with at least one terminal.

The invention also relates to a subassembly hereof.

The invention further relates to a method of manufacturing such a subassembly and to a method of manufacturing such a package.

Such a package is known from is known from U.S. Pat. No. 6,486,499. The known package is a package aimed for one or more light emitting diodes. The interconnect element is provided with a thermally conducting layer. Examples hereof include Si, AlN and BeO, and particularly Si. An additional layer of SiO₂ may be present, if electrical isolation between the semiconductor devices and the first side of the interconnect element is desired. The light emitting diodes are assembled to the element, and their bond pads are electrically coupled to the contact pads on the interconnect element with solder balls. The interconnect element is assembled to a further carrier in the package. The at least one terminal of the interconnect element is coupled to such a carrier with wirebonds. A second terminal may be provided through the interconnect element.

It is however a disadvantage of the known device that for a proper heat transfer through an interconnect element based on a silicon substrate a thickness of less than 250 microns is desired. Simultaneously, silicon substrates with such a thickness tend to be very brittle and sensitive to fracture. If the substrate thickness is even further reduced, silicon may become flexible, but then the interconnect element is not suitable anymore for as a supporting element of the package.

It is therefore an object of the invention to provide a package of the kind mentioned in the opening paragraph which allows an adequate dissipation of heat and simultaneously is sufficiently mechanically stable.

This object is achieved in that the package comprises an encapsulation encapsulating the at least one semiconductor device, and a heatsink that is thermally coupled to the interconnect element over the thermally conductive layer, wherein at least one component of the encapsulation and the heatsink has an interface with the interconnect element, which interface extends over substantially the complete side to which the said component is attached, and wherein the thermally conductive layer is electrically insulating, such that the isolation and the thermally conducting layer electrically isolate the electrical interconnects from each other.

In the invention, the thermal capability of the interconnect element is improved in that the thermally conductive layer is not anymore the supporting element. The supporting element is now either the encapsulation or the heat sink or optionally both. In order that one of them may function as a supporting element for the interconnect element, there is a substantially continuous interface between the supporting element and the interconnect element. Such a continuous interface extends over substantially the complete side of the interconnect element. The term ‘substantially extending’ is here to understood as synonym to substantially continuous. Additionally, the interface is evidently not present at areas in which a semiconductor device and/or one electrical connection between the contact pads of the semiconductor device and the interconnect element is present. Moreover, the interface may be absent in separation lanes and the like structures. However, the supporting element will extend over a major portion of the interconnect element, so as to operate as a supporting element.

Additionally, this structure has the advantage that the thermally conducting layer may be coupled adequately and on several positions to a heat sink. Evidently, this improves the heat dissipation. In order to prevent the existence of any short circuit, the said interconnects are mutually electrically insulated. Most interconnects are moreover electrically insulated from the heatsink. This is particularly achieved, without any increase in thermal resistance, in that the thermally conductive layer is chosen to be electrically insulating. For reason of clarity it is added that the heatsink is generally used as one of the contacts, and more specifically as the grounding contact. Thus any interconnect that should be connected to ground, may have a pad that is exposed to the heatsink. The exact number hereof is evidently dependent on the specific application.

Another advantage of the package of the invention is that it is self-supporting. Actually, no additional carrier is needed, if so desired. This reduces the assembly costs and complexity, and also reduces the total thickness of the package, which is an important parameter in several applications, particularly in the field of portable devices. If surface-mountable terminals are desired, the terminals—which may here be thus real terminals and not just internal contact pads—can be provided at the second side of the interconnect element, and adjacent to the heat sink. However, alternatively, the terminals may be designed to be suitable for coupling to any connector, including spring-based connectors and flexfoils.

The package of the invention is evidently particularly designed for applications in which there is a need of power dissipation. Light-emitting diodes are hereof an example. The semiconductor device could however also be a microprocessor, such as those used in portable computers, and as transceiver and baseband ICs in portable applications such as mobile phones. Additionally, the semiconductor device may be a power device, such as a power management unit for a mobile phone or for a computer, or power amplifiers for RF applications.

In addition, the package of the invention may be exploited effectively, if more than one semiconductor device is present. In one embodiment of such multi-chip packages the devices are present adjacent to each other. The encapsulation then is very effective to create a mechanically stable package. In another embodiment, a first semiconductor device is assembled to a surface of a second semiconductor device. Such systems, also known as stacked dies packages or chip-on-chip packages, provide a high density on a relatively limited area. Additionally, at most one of both semiconductor devices may be attached to a heat sink. The benefit of the invention is here the proper heat transfer. With a suitable design, even both devices may be coupled to the interconnect element: one with its backside, another through solder bumps in a flip-chip orientation.

In one important embodiment, the thermally conducting layer is provided with stress-release lanes. The thermally conducting layer is generally a material such as diamond or aluminium nitride. This has a coefficient of thermal expansion that is different from that of the heatsink material and probably also from that of the encapsulation. It is therefore suitable to provide such stress-release lanes. In such lanes, the thermally conducting layer is removed. This of course reduces the spreading of the heat in lateral directions, but this is not considered problematic. First, the heat sink also will have a heat-spreading effect. Secondly, a major function of the heat spreading in the thermally conducting layer is the spreading from the point-alike semiconductor device over a larger surface area. This major function is not at all affected. Thirdly, particularly in embodiments with light emitting diodes, the generated heat may be approximately the same for every area.

In a further modification of this embodiment, the interconnects are provided with spring-structures that enable contraction and expansion during thermal cycling, said spring-structures being present in the stress-relieve lanes. This spring-structures allow a further stress-release. This modification is also very well suitable for use in packages that are to be mounted on a printed circuit board. The spring-structures result therein that the expansion may be locally larger, so as to protect structures, as the one or more assembled semiconductor devices that are not capable of substantial expansion. The spring-like structures are suitable embodied in combination with a thermally conductive material of diamond, but they can of course be implemented with other layers as well. Moreover, it is not excluded, in general, that there may be more than one thermally conducting layer, of which only one is electrically insulating. For instance, one may use a combination of BeO and Si or of AlN and Si.

The invention also relates to subassemblies of this package and methods of manufacturing hereof Particularly, there are two subassemblies: one with the encapsulation attached to the interconnect element, and one with the heatsink attached to the interconnect element.

Such subassemblies are self-supporting and can be used in an assembly factory. Moreover, they may be prepared with the method of the invention. This involves the use of a sacrificial substrate that is subsequently removed. A most suitable sacrificial substrate is a semiconductor substrate, as processing of semiconductor substrates is well-known and equipment and facilities are available therefore. Another advantage is that the use of a semiconductor substrate allows the integration of semiconductor elements, such as ESD-protections, driver circuits and photodiodes for sensor applications, as already mentioned in the prior art document.

These and other aspects of the invention will be further elucidated with reference to the Figures, in which:

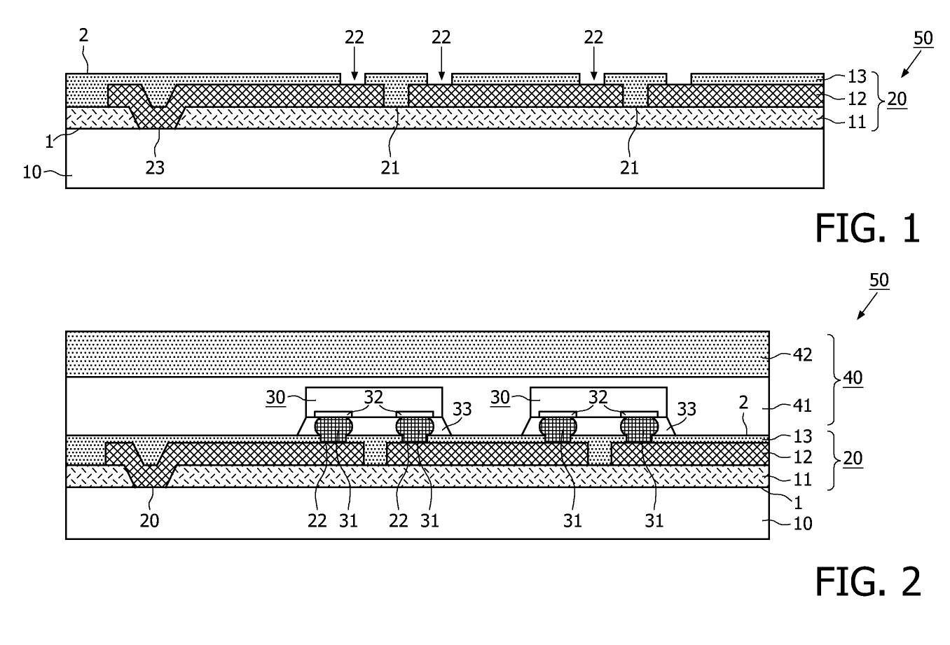

FIGS. 1-3 show in cross-sectional, diagrammatical view three stages in the manufacture of a first subassembly according to the invention;

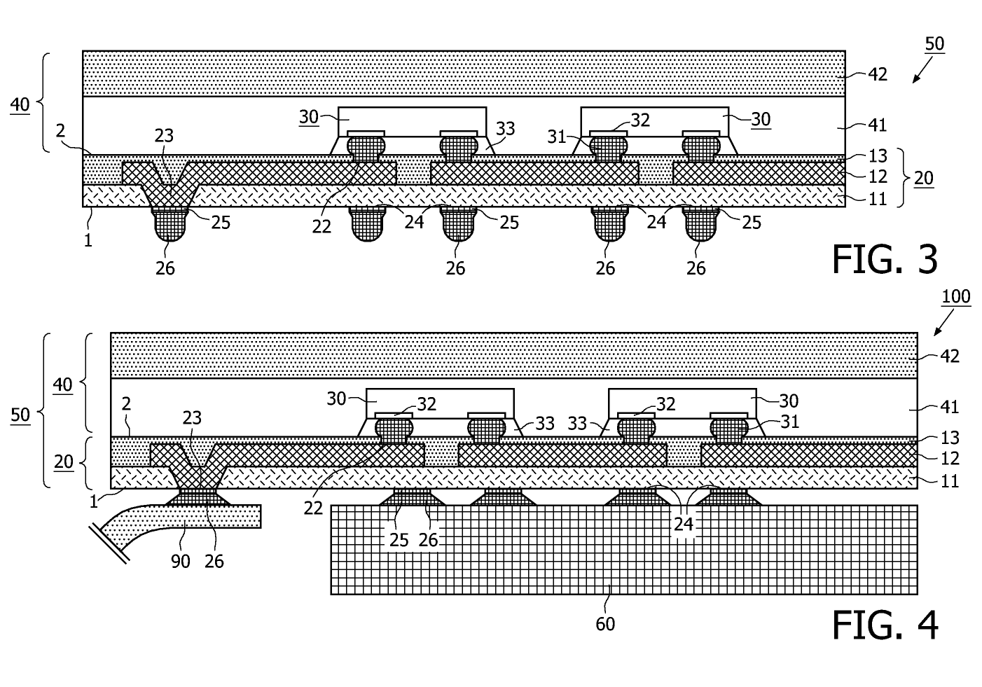

FIG. 4 shows the package of the invention made with the subassembly of FIG. 3;

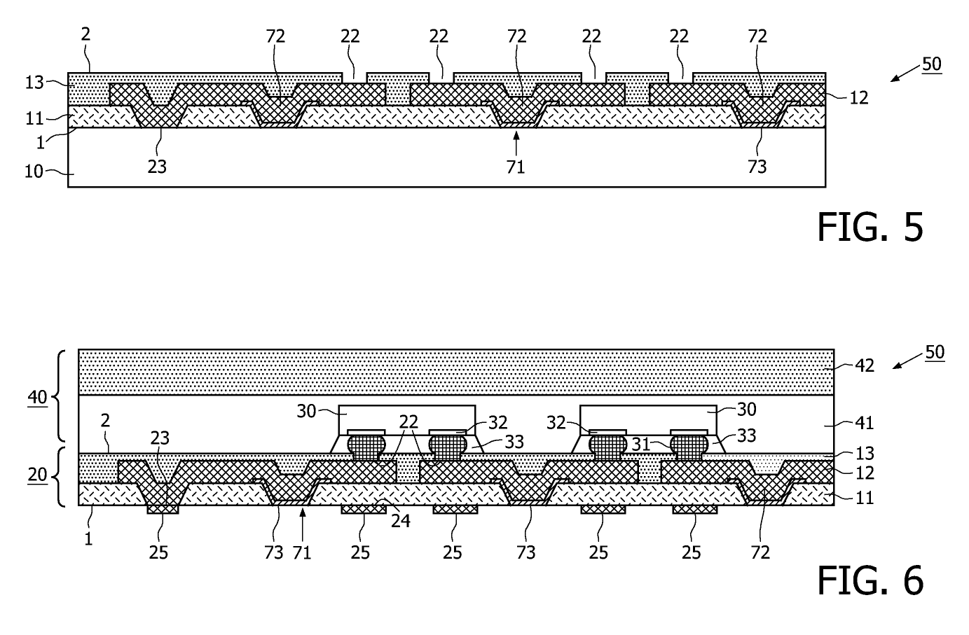

FIGS. 5-7 show in cross-sectional, diagrammatical view three stages in the manufacture of a second subassembly according to the invention;

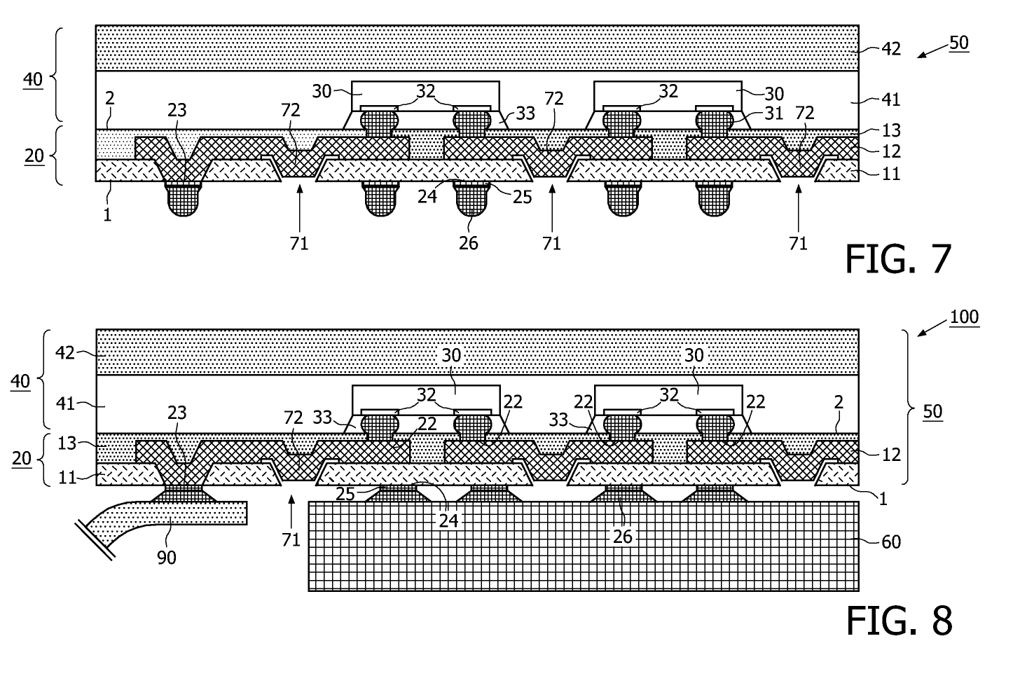

FIG. 8 shows the package of the invention made with the subassembly of FIG. 7;

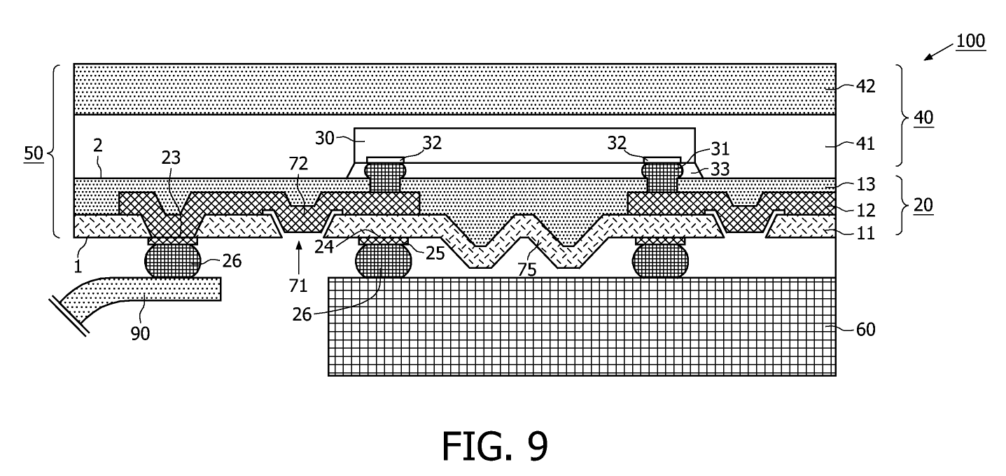

FIG. 9 shows a third embodiment of the package of the invention;

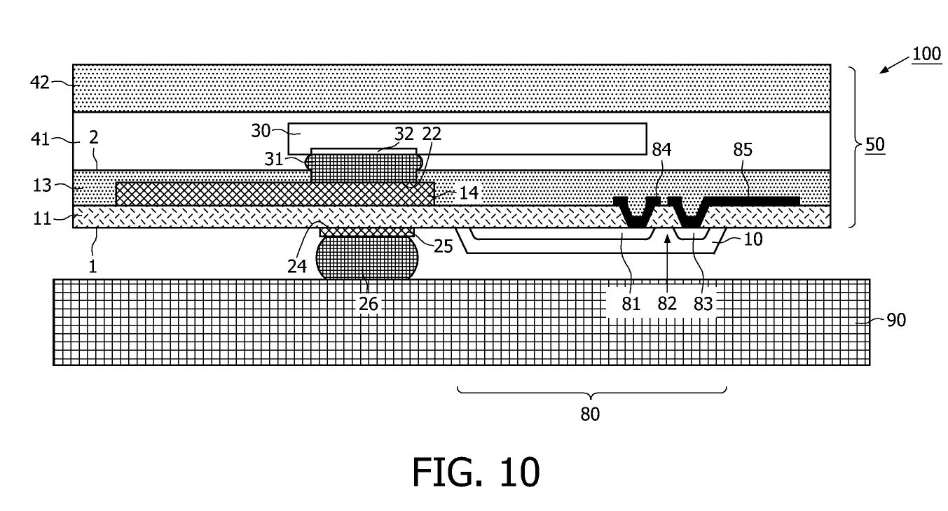

FIG. 10 shows a fourth embodiment of the package of the invention;

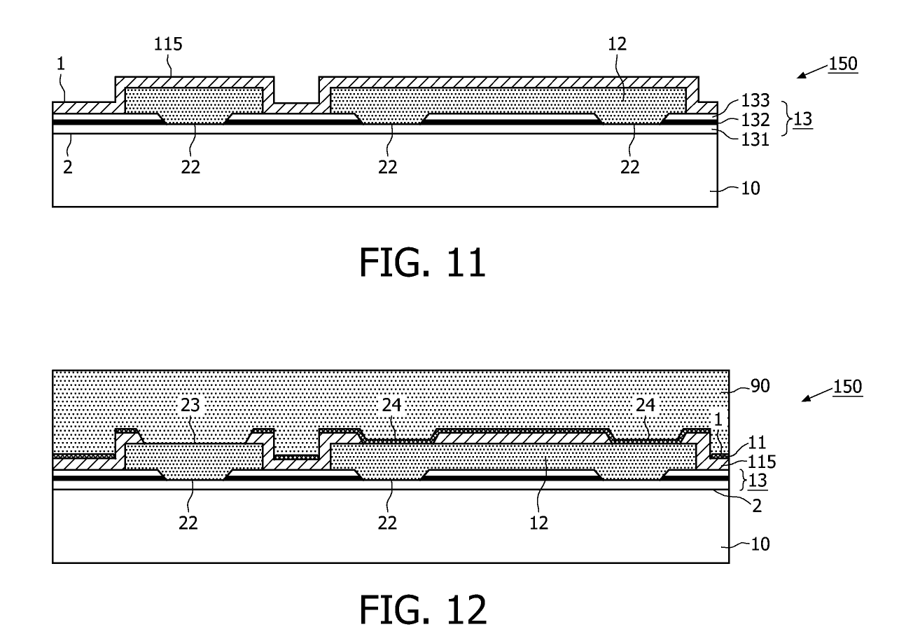

FIGS. 11-13 show in cross-sectional, diagrammatical view three stages in the manufacture of a third subassembly according to the invention, and

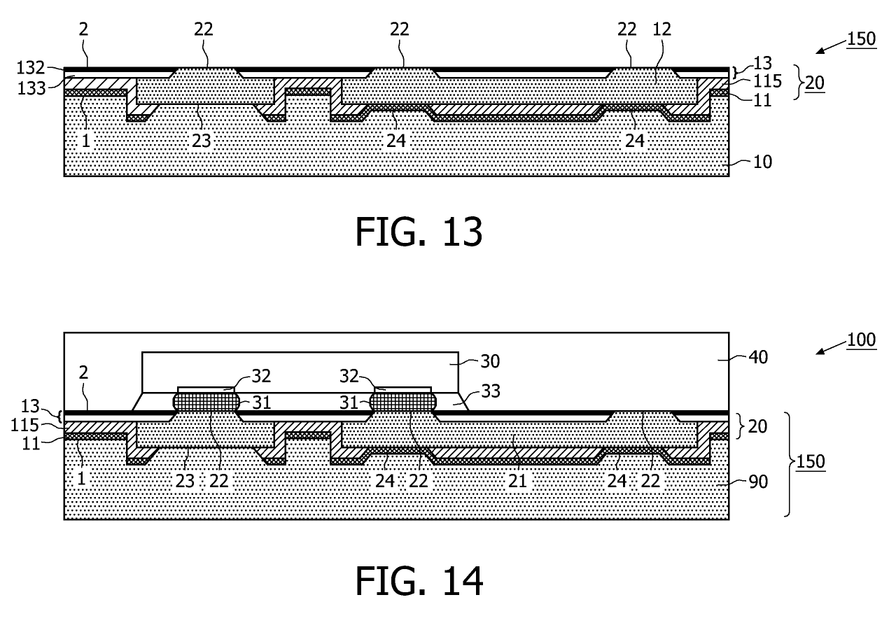

FIG. 14 shows the package of the invention made with the subassembly of FIG. 13.

The Figures are not drawn to scale and purely diagrammatical. Same reference numerals in different figures relate to equal or corresponding parts. The figures are drawn for illustrative purposes only and should not be understood as limiting the invention. In fact, many more examples will become apparent to the skilled person on the basis of the figure description. Although the figures shown several stages in the manufacture of a single component only, it is observed that the steps in the method will generally take place on plate-level, after which separation into individual elements take place. This separation may be carried out with conventional techniques. Suitably, separation lanes have already been defined in particularly the subassemblies 50, 150 during the manufacturing process.

FIG. 1 shows in cross-sectional view a first stage in the manufacture of a subassembly 50 comprising the encapsulation and without heat sink. At this stage, the subassembly 50 is merely a substrate 10 with a couple of layers thereon. The substrate 10 is in this example a semiconductor substrate, particularly of Si, and is provided with an oxide layer, which however is not shown. Such oxide layer is prepared according to conventional processing. On top of the substrate 10, an interconnect element 20 is present, which has a first side 1 and a second side 2. At the first side 1 of the interconnect element 20, on the substrate 10, a thermally conducting and electrically insulating layer 11 is provided. In this case, this is a diamond layer. This is in this example polycrystalline and provided by chemical vapour deposition, particularly by PECVD at 800° C. It is deposited in a thickness of generally less than 10 microns, preferably in the range of 1-5 um thickness. The diamond layer is patterned to create terminal areas. The patterning of the diamond layer is carried out with reactive ion etching. The terminal areas are filled with an electrically conductive material such as Cu, Al, Ni, ITO, TiN or alloys of such metals to create the terminals 23. Although not indicated, it is suitable to use conventional barrier layers and/or adhesion layers. Also, the manufacture of the interconnects 12 of this electrically conductive material is well-known in the art and may be carried out with various techniques, such as by sputtering, vapour deposition, inkjetprinting or galvanically, by electroless growth or electroplating. Here, use is made of electroplating of Cu. The material is deposited in a thickness of 5-10 microns in this example. The electrically conductive material extends on the thermally conducting layer 11 to form a system of interconnects 12. The design hereof is predefined. In this example, which relates to light-emitting diodes, the design may be relatively simple, in that interconnection between the contact pads 22 of neighbouring devices is implemented. These devices are then coupled in series. Although merely a single-layered system of interconnects 12 is shown, this system 12 may be multilayered and such that the individual layers are electrically isolated by electrically insulating material. This material could be thermally conductive. Alternatively, specific thermal paths may be created between the contact pads 22 and the thermally conducting layer 11. At the second side 2 of the interconnect element 20, the interconnects 12 are subsequently covered with an electrical isolation 13. This isolation 13 consists in this example of a solder resist material, but could be alternatively an inorganic passivation layer, a resin layer or any other electrically insulating layer. Suitably, the isolation 13 comprises a layer that is photosensitive so as to allow photolithography without the use of an additional mask. Nevertheless and alternatively, such a layer could be provided by any printing or vapour deposition method. In this example, such is made of a photosensitive form of polyimide, such as commercially available. The isolation 13 extends on top of the interconnects 12 as well in areas 21 in between of the interconnects 12. It mutually insulates the interconnects, together with the thermally conductive layer. Herewith the interconnect element 20 is formed, which comprises basically the interconnects 12 as well as the thermally conductive layer 11 and the electrical isolation 13. Optionally, the interconnect element 20 may contain elements defined in the semiconductor substrate 10 and maintained in islands therein.

FIG. 2 shown the subassembly 50 at a second stage. At this stage the semiconductor devices 30 are assembled to the interconnect element 20, and its bond pads 32 are electrically coupled to the contact pads 22 of the interconnect element 20. This is achieved, in this example, with solder balls 31. The solder balls may contain a high melting solder, such as a lead-containing material, if there are further solder balls that connect the subassembly with a further element. However, this is not necessary, as known to the specialist in the field of soldering. The solder balls 31 are surrounded with an underfilling material 33. Instead of assembling the devices 30 in a flip-chip orientation to the interconnect element 20, they may be assembled face-up. The bond pads 32 are then coupled to the contact pads 22 by further connecting elements, such as wirebonds.

The active devices 30, herein light-emitting diodes, are encapsulated by an encapsulation 40. This encapsulation 40 comprises in this example a bilayer system of an adhesive 41 and a glass plate 42. Alternatively, use can be made of an overmoulded encapsulation 40. Specific materials are known to the skilled person in the art. An acrylate adhesive 41 appears appropriate, as it has a relatively low glass transition temperature and thus allows to accommodate the thermal expansion of the semiconductor devices. Particularly, there is no need for silicone paste filling, as in prior art. In view of the application, the encapsulation is suitably transparent. In another modification, the semiconductor devices 30 are provided into the encapsulation 40 before assembly to the interconnect element 20. This is suitably achieved by providing recesses in the encapsulation, in which the semiconductor devices 30 fit. Attachment of the devices into the recesses is suitably achieved with a die attach adhesive. Attachment of the encapsulation 40 with semiconductor devices 30 to the interconnect element is suitably achieved with an adhesive or an underfill. It is particularly suitable thereto, that the adhesive or underfill is already provided onto at least one of the interconnect element 20 and the encapsulation 40 prior to the assembly step. One suitable example hereof is the use of an underfilling material, that liquefies on gentle heating, such that the solder balls 31 sink through this material and make contact with the contact pads 22. Such a material, for instance an acrylate or a polyimide, may thereafter be cured at an elevated temperature.

This further modification is particularly suitable for light emitting diodes. In that case, there is a plurality of diodes that preferably all have the same dimensions. The definition of cavities is therefore not problematic. The encapsulation 40 is in that case suitably a plate of a glass or other ceramic material that is suitably transparent for a desired set of wavelength. Alternatively, the encapsulation 40 may be provided by replica moulding technique.

FIG. 3 shows the subassembly 50 in a third, final stage. The substrate 10 has been completely removed in this example. This has been achieved with grinding and etching, although peeling the substrate is not excluded. Herewith, the terminals 23 are exposed. Additionally exposed are contact areas 24 of the thermally conducting layer 11. Thereafter metal pads 25 are defined, for instance of Ni, or NiAu, i.e. a material that wets the solder material. The metal pads 25 are subsequently provided with solder balls 26. Suitably, use is herein made of solder flux (not shown).

FIG. 4 shows the resulting package 100, in which the heat sink 60 is attached to the solder balls on the contact areas 24 of the thermally conducting layer. A flexfoil 90 is attached, in this example to the solder ball on the terminal 20. Evidently, other elements may be provided to the terminal 20 alternatively, such as one or more bondwires, spring-like connectors or the like. Additionally, the heat sink 60 could be applied to the thermally conducting layer 11 in other manners, such as with glue.

FIGS. 5-8 show a second embodiment of the invention. In this embodiment, stress-relieve lanes 71 are provided in the thermally conducting layer 11. Spring-like structures 72 are provided as part of the interconnects 12. This is achieved with the use of a sacrificial layer 73.

FIG. 5 shows the subassembly 50 in a first stage, corresponding to FIG. 1. The stress-relieve lanes 71 are defined in the same step as the terminal areas 23, again by patterning of the thermally conductive layer 11. It will be understood that the stress-release lanes 71 preferably extend in two or more directions so as to create islands of the thermally conducting layer 11. The lanes may additionally be circular or oval or the like. Then a sacrificial layer 73 is deposited selectively, i.e. only in the stress-relieve lanes 71. This sacrificial layer 73 is suitable an oxide, that is provided as TEOS (tetra-ethylene orthosilicate) and converted in a subsequent heat treatment. The provision of the sacrificial layer may be carried out by deposition through a mask, by printing and/or by subsequent removal of the layer in the areas in which it is not desired. It is important for the creation of the spring-like structures 72 in the interconnects 12 that the sacrificial layer 73 extends on top of the thermally conductive layer 11. Suitably, the sacrificial layer 73 is thinner than the thermally conductive layer 11.

FIG. 6 shows the subassembly 50 in a second stage, corresponding to FIG. 3. Herein, the semiconductor devices 30 are assembled. The bond pads 32 thereof are coupled to the contact pads 22 with an electrically conductive connection, here solder balls 31. Also, an encapsulation 40 is provided. Thereafter, the substrate 10 has been removed by grinding and etching from the second side thereof. This has exposed the terminals 23 and contact areas 24 to the thermally conducting layer. It additionally has exposed the sacrificial layer 73. Prior to removal of the sacrificial layer, now, the metal pads 25 are applied to the contact areas 24 and the terminals 23. Also the solder balls may be provided, although that is not done in this example. The reason thereto is that it is easier to provide layers on a planar substrate.

FIG. 7 shows the final subassembly 50 after removal of the sacrificial layer 73 and the provision of solder balls 26. As is clear from the figure, the spring-like structures 72 are herein released and may expand laterally, while neither the thermally conducting layer 11 nor the semiconductor devices 30 need to do so. In this manner, the stress is thus locally released, and not spread out over the complete surface area.

FIG. 8 shows the resulting package with the heatsink 60 and the flexfoil 90. This Figure clearly shows the benefit of the stress-relieve lanes 71 and the spring-like structures, in that differences in thermal expansion between the heat sink 90 and the interconnects 12 on the one hand, and the thermally conductive layer 11 and the semiconductor devices 30 on the other hand, can be compensated adequately and locally.

FIG. 9 shows another embodiment of the package 100. The main difference with the package of FIG. 8 is herein that also the thermally conductive layer 11 is provided with a non-planar form in other to release stress. This structure 75 allows the release of stress as a result of a mismatch of the semiconductor device 30 and the material of the thermally conductive layer 11. It can be suitably made by etching of grooves in the semiconductor substrate 10 prior to deposition of the thermally conductive layer 11

FIG. 10 shows in a cross-sectional view a detail of a further embodiment of the device. Herein, the semiconductor substrate 10 is only partially removed, and an electrical element 80 is defined in the semiconductor substrate. In this example the element 80 is a photodiode, with a n-type region 81 and a p-type region 82, in between of which an intrinsic region (I-type) 83 is present. These regions and junctions are defined prior to the deposition of the thermally conductive layer 11. This is compatible, as a diamond layer 11 is deposited at 800° C., which is lower than the temperature needed for the deposition of the junctions, and which does not harm the junctions. Specific interconnects 84, 85 are defined through the thermally conducting layer 11 and on this thermally conducting layer 11. Suitably, these are thinner than those for the light emitting diodes, although this may be modified and optimized. They are isolated by the electrical isolation 13, and further coupled to the system of interconnects 12 by not shown contacts. Also or alternatively, the element 80 may be provided with a separate terminal for external connection. The photodiode can be used as a photodetector or a temperature sensor close or even underneath the individual semiconductor devices 30, and in particular light emitting diodes.

FIG. 11 shows a first step in a further embodiment of the invention. In this case, a subassembly 150 is made of the heat sink 90 and the interconnect element 20. Thereto, the semiconductor devices 30 and the encapsulation 40 may be provided to manufacture the package. In this case, the second side 2 of the interconnect element 20 is present on the substrate 10, instead of the first side 1 as in the previous embodiments. The insulation 13 is herein deposited on the substrate 10, which is covered with an oxide layer 131. This first oxide 131 is suitably provided as a thermal oxide. The insulation 13 of this example comprises a stack of a nitride 132 and an oxide 133. The nitride 132 and the oxide 133 are suitably deposited by chemical vapour deposition. The nitride 132 and the oxide 133 are subsequently patterned to define the contact pads 22. The semiconductor device 30 may be assembled to these contact pads 22 with solder balls. Interconnects 12 are defined on the insulation 13. Suitably again, these interconnects are made of Cu by electroplating is sufficient thickness. The resulting structure is then covered with an insulating layer 115. This is in this example a nitride. It is observed that the deposition of the insulating layer 115 is an optional step, and that it may be left out.

FIG. 12 shows the subassembly 150 in a second stage. Herein, first a thermally conducting, electrically insulating layer 11 is deposited on the insulating layer 115, if present. Use is made of AlN in this example. The thermally conducting layer 11 is deposited after patterning of the insulating layer 115. At those areas at which there is solely a thermally conducting layer, the contact areas 24 between the thermally conducting layer 11 (and the interconnect 12 thereon) and the heat sink are defined. Additionally, the thermally conducting layer 11 is patterned, and thereafter again the insulating layer 115. This creates the terminal 20. Finally, the heat sink 90 is provided by electroplating. The heat sink has a thickness of about 50 to 100 microns, but this may be less or more as desired. Electroplating a heatsink of such a thickness has the advantage that it is provided with an inherent low stress, that is very regularly.

FIG. 13 shows the subassembly 150 after removal of the substrate 10. Additionally, the oxide layer 131 is removed. Now, the contact pads 22 are exposed. The subassembly 150 obtains its stability from the presence of the heatsink 90 which has an interface with the interconnect element 20 that is substantially continuous, e.g. extends over substantially one complete side of the interconnect element 20.

FIG. 14 shows the resulting package 100 after provision of at least one semiconductor device 30 and an encapsulation 40. In this example, the semiconductor device 30 is assembled in a flip-chip orientation and its bond pads 32 are electrically coupled to the contact pads 22 of the interconnect element 20 through solder balls 31. It is present on the second side 2 of the interconnect element 20. An underfilling material 33 is provided for filling the space between the semiconductor device 30 and the interconnect element 20. The encapsulation is for instance an epoxy overmould, and possibly a transparent epoxy overmould.

1. A package for at least one semiconductor device comprising:
at least one semiconductor device provided with bond pads,
an encapsulation encapsulating the at least one semiconductor device,
an interconnect element with a first side and an opposite second side, which element comprises a system of electrical interconnects that is at least substantially covered by a thermally conductive, electrically insulating layer at the first side and that is provided with an electric isolation at the second side, such that the isolation and the thermally conducting layer electrically isolate the electrical interconnects from each other, which electric isolation is provided with apertures that expose contact pads defined in the interconnects, to which contact pads the bond pads of the at least one semiconductor device are electrically coupled, which system of electrical interconnects is provided with at least one terminal, and
a heatsink that is thermally coupled to the interconnect element over the thermally conductive, electrically insulating layer,
wherein at least one component of the encapsulation and the heatsink has an interface with the interconnect element, which interface extends over substantially the complete side to which the said component is attached.

2. A subassembly comprising:
at least one semiconductor device provided with bond pads,
an interconnect element with a first side and an opposite second side, which element comprises a system of electrical interconnects that is at least substantially covered by a thermally conductive, electrically insulating layer at the first side and that is provided with an electric isolation at the second side, such that the isolation and the thermally conducting layer electrically isolate the electrical interconnects from each other, which electric isolation is provided with apertures that expose contact pads defined in the interconnects, to which contact pads the bond pads of the at least one semiconductor device are electrically coupled, which system of electrical interconnects is provided with at least one terminal,
an encapsulation encapsulating the at least one semiconductor device and having an interface with the interconnect element, which interface extends over substantially the complete first side.

3. (canceled)

4. A method of manufacturing a subassembly, comprising the steps of:
providing a temporary substrate;
providing a thermally conducting, electrically insulating layer on the substrate;
patterning the thermally conducting layer to define at least one terminal area;
providing a system of electrical interconnects on the patterned thermally conducting layer, wherein terminals are formed in the at least one terminal area;
applying an electrical isolation that substantially covers the electrical interconnects with the exception of contact pads, such that the isolation and the thermally conducting layer electrically isolate the electrical interconnects from each other;
assembling the at least one semiconductor device to system and electrically coupling its bond pads to the contact pads,
providing an encapsulation that encapsulates the at least one semiconductor device and such that it has an interface with the electrical isolation that extends over substantially the complete electrical isolation, and
at least partially removing the temporary substrate to expose the at least one terminal area and contact areas of the thermally conducting layer.

5. (canceled)

6. A method as claimed in claim 4, wherein the temporary substrate is a semiconductor substrate.

7. A method as claimed in claim 6, wherein the semiconductor substrate comprises at least one electrical component that is coupled to the assembled semiconductor devices through the system of interconnects.

8. A method as claimed in claim 4, wherein the encapsulation is attached to the semiconductor devices prior to the assembly, such that with the assembly of the semiconductor device also the encapsulation is provided.

9. A package as claimed in claim 1, wherein the semiconductor devices are light emitting components.

10. A package as claimed in claim 1, wherein a plurality of semiconductor devices are assembled.

11. A package as claimed in claim 1, wherein the thermally conducting layer is locally removed to define stress-relieve lanes.

12. A package as claimed in claim 11, wherein the interconnects are provided with spring-structures that enable contraction and expansion during thermal cycling, said spring-structures being present in the stress-relieve lanes.

13. A method as claimed in claim 4, wherein:
stress-relieve lanes are defined in the patterning of the thermally conducting layer,
a sacrificial layer is applied in the stress-relieve lanes before the provision of the system of interconnects, said sacrificial layer having a smaller thickness than the thermally conducting layer and extending on the thermally conducting layer;
the system of interconnects is provided such that the interconnects fill the stress-release lanes,
the removal of the temporary substrate also exposes the sacrificial layer in the stress-release lanes, and
the sacrificial layer is removed to create spring-like structures in the interconnects.

14. A method of manufacturing a package as claimed in claim 1, such that the heat sink is thermally coupled to the thermally conducting layer.

15. A method of manufacturing a package as claimed in claim 1, wherein at least one semiconductor device is assembled to the second side of the interconnect element in the subassembly and its bond pads are electrically coupled to the contact pads, and an encapsulation is provided that encapsulates the at least one semiconductor device.

16. A method as claimed in claim 15, wherein the encapsulation has been provided to the at least one semiconductor device prior to assembly, such that it is provided to the subassembly in the assembly of the at least one semiconductor device.
